(19) United States
(12) Patent Application Publication
(10) Pub. No.: US 2025/0336644 A1
(43) Pub. Date: Oct. 30, 2025

(54) STAGE SPEED OBTAINING METHOD, MULTIPLE CHARGED PARTICLE BEAM WRITING METHOD, AND METHOD FOR OBTAINING COMBINATION OF STAGE SPEED AND MULTIPLICITY IN MULTIPLE CHARGED PARTICLE BEAM WRITING

(71) Applicant: NuFlare Technology, Inc., Yokohama-shi (JP)

(72) Inventors: Honoka BEPPU, Yokohama-shi (JP); Haruyuki NOMURA, Yokohama-shi (JP)

(73) Assignee: NuFlare Technology, Inc., Yokohama-shi (JP)

(21) Appl. No.: 19/184,543

(22) Filed: Apr. 21, 2025

(30) Foreign Application Priority Data
Apr. 26, 2024 (JP) 2024-072282
Apr. 17, 2025 (JP) 2025-068004

(51) Int. Cl. H01J 37/317; H01J 37/302

(52) U.S. Cl. CPC H01J 37/3177; H01J 37/3026; H01J 2237/24507; H01J 2237/31762; H01J 2237/31764; H01J 2237/31769

(57) ABSTRACT

A stage speed obtaining method for performing writing on a substrate with a charged particle beam while moving a stage on which the substrate coated with resist is placed includes storing, in a storage device, relation data among a stage speed of the stage, a dose for one writing processing, and a temperature increase of the resist, reading the relation data from the storage device by a processing circuit, obtaining, using the relation data, a stage speed at which the temperature increase of the resist is equal to or less than a preset allowable temperature increase, and outputting an obtained stage speed.

### CROSS-REFERENCE TO RELATED APPLICATION

This application is based upon and claims the benefit of priority from prior Japanese Patent Application No. 2024-072282 filed on Apr. 26, 2024 in Japan, and prior Japanese Patent Application No. 2025-068004 filed on Apr. 17, 2025 in Japan, the entire contents of which are incorporated herein by reference.

### BACKGROUND OF THE INVENTION

### Field of the Invention

Embodiments of the present invention relate to a stage speed obtaining method, a stage speed obtaining apparatus, a multiple charged particle beam writing method, a method for obtaining combination of a stage speed and multiplicity in multiple charged particle beam writing, a multiple charged particle beam writing apparatus, and a non-transitory computer-readable storage medium storing a program thereon. For example, embodiments relate to a writing method according to which an increased temperature of resist applied on a substrate used in multiple writing is suppressed within an allowable temperature increase.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is decreasing year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single beam. Regarding the multiple beam writing, it has turned out that although the current density is smaller than that of single beam writing, a significant resist heating occurs depending on writing conditions. Therefore, a problem may arise such as uncorrectable degradation of CD (critical dimension) accuracy, or alteration (deterioration) of resist. In order to cope with this problem, it is necessary to suppress increase of temperature of the substrate generated by writing processing. On the other hand, if writing processing is performed so that the temperature increase of the substrate may be suppressed, it poses a problem of throughput degradation. For this reason, it needs to increase throughput as much as possible in the range where no uncorrectable CD accuracy degradation occurs or no resist alteration occurs.

There is disclosed a method in which a temperature distribution is estimated at a target object to be written with a predetermined multiplicity and the multiplicity for each pattern is determined based on the temperature distribution (e.g., refer to Japanese Patent Application Laid-open (JP-A) No. 2022-030301).

### BRIEF SUMMARY OF THE INVENTION

According to one aspect of the present invention, a stage speed obtaining method for performing writing on a substrate with a charged particle beam while moving a stage on which the substrate coated with resist is placed includes
storing, in a storage device, relation data among a stage speed of the stage, a dose for one writing processing, and a temperature increase of the resist, and
reading the relation data from the storage device by a processing circuit, obtaining, using the relation data, a stage speed at which the temperature increase of the resist is one of equal to and less than a preset allowable temperature increase, and outputting an obtained stage speed.

According to another aspect of the present invention, a multiple charged particle beam writing method includes
storing, in a storage device, relation data among a stage speed of a stage on which a substrate coated with resist is to be placed, a dose for each writing processing of multiple writing, and a temperature increase of the resist,
reading the relation data from the storage device, and obtaining, using the relation data, a combination of a stage speed, at which writing can be performed in a range where the temperature increase of the resist is within an allowable temperature increase, and multiplicity of the multiple writing, and
writing a pattern with multiple charged particle beams onto the substrate placed on the stage through writing processing in accordance with the combination obtained of the stage speed and the multiplicity.

According to yet another aspect of the present invention, a method for obtaining a combination of a stage speed and multiplicity in multiple charged particle beam writing includes
storing, in a storage device, relation data among a stage speed of a stage on which a substrate coated with resist is to be placed, a dose for each writing processing of multiple writing, and a temperature increase of the resist, and
reading the relation data from the storage device, obtaining, using the relation data, a combination of a stage speed, at which writing can be performed in a range where the temperature increase of the resist is within an allowable temperature increase, and multiplicity of the multiple writing, and outputting the combination obtained.

According to yet another aspect of the present invention, a multiple charged particle beam writing apparatus includes
a storage device to store therein relation data among a stage speed of a stage on which a substrate coated with resist is to be placed, a dose for each writing processing of multiple writing, and a temperature increase of the resist,
a combination obtaining circuit to read the relation data from the storage device, and to obtain, using the relation data, a combination of a stage speed, at which writing can be performed in a range where the temperature increase of the resist is within an allowable temperature increase, and multiplicity of the multiple writing, and
a writing mechanism to include the stage and an optical system which generates multiple charged particle beams and controls a trajectory of the multiple charged particle beams, and to write a pattern with the multiple charged particle beams onto the substrate placed on the stage through writing processing in accordance with an obtained combination of the stage speed and the multiplicity.

According to yet another aspect of the present invention, a non-transitory computer-readable storage medium storing a program for causing a computer to execute processing including
storing, in a storage device, relation data among a stage speed of a stage on which a substrate coated with resist is to be placed in multiple beam writing, a dose for each writing processing of multiple writing, and a temperature increase of the resist, and
reading the relation data from the storage device, obtaining, using the relation data, a combination of a stage speed, at which writing can be performed in a range where the temperature increase of the resist is within an allowable temperature increase, and multiplicity of the multiple writing, and outputting an obtained combination.

### BRIEF DESCRIPTION OF THE DRAWINGS

FIG. 1 is an illustration showing a schematic diagram of an example of a configuration of a writing apparatus according to a first embodiment;

FIG. 2 is a conceptual diagram showing an example of a configuration of a shaping aperture array substrate according to the first embodiment;

FIG. 3 is a sectional view showing an example of a configuration of a blanking aperture array mechanism according to the first embodiment;

FIG. 4 is a conceptual diagram explaining an example of a writing region according to the first embodiment;

FIG. 5 is an illustration showing an example of a multiple beam array according to the first embodiment;

FIG. 6 is an illustration explaining an example of a multiple beam writing operation according to the first embodiment;

FIG. 7 is an illustration showing an example of a relation between a resist temperature increase and pattern dimension according to the first embodiment;

FIG. 8 is an illustration showing an example of a relation between increase of temperature of resist and alteration of the resist according to the first embodiment;

FIG. 9 is a flowchart showing an example of main steps of a writing method according to the first embodiment;

FIG. 10 is an illustration showing an example of a resist temperature increase model according to the first embodiment;

FIG. 11 is an illustration showing an example of relation data according to the first embodiment;

FIG. 12 is a block diagram showing an example of the internal configuration of a combination obtaining unit according to the first embodiment;

FIG. 13 is an illustration showing an example of a relation between a stage speed V_{stage} at an allowable temperature increase and a dose D for each writing processing in multiple writing according to the first embodiment;

FIG. 14 is an illustration showing an example of a relation between a stage speed V_{stage} at an allowable temperature increase and a dose D for each writing processing in multiple writing, and an example of a dose for each multiplicity according to the first embodiment;

FIG. 15 is an illustration showing an example of a relation among a writing time, a resist sensitivity, and multiplicity according to the first embodiment;

FIG. 16 is an illustration showing another example of a relation among a writing time, a resist sensitivity, and multiplicity according to the first embodiment;

FIG. 17 is a block diagram showing an example of an internal configuration of a combination obtaining unit according to a second embodiment;

FIG. 18 is a flowchart showing an example of some portions of main steps of a writing method according to the second embodiment; and

FIG. 19 is a flowchart showing an example of the other portions of the main steps of the writing method according to the second embodiment.

### DETAILED DESCRIPTION OF THE INVENTION

Embodiments below provide an apparatus and method by which writing conditions for suppressing an increase in writing time can be obtained in the range where no uncorrectable CD accuracy degradation occurs or no resist alteration (deterioration) occurs.

Embodiments below describe a configuration in which an electron beam is used as an example of a charged particle beam. The charged particle beam is not limited to the electron beam, and other charged particle beams such as an ion beam may also be used.

### First Embodiment

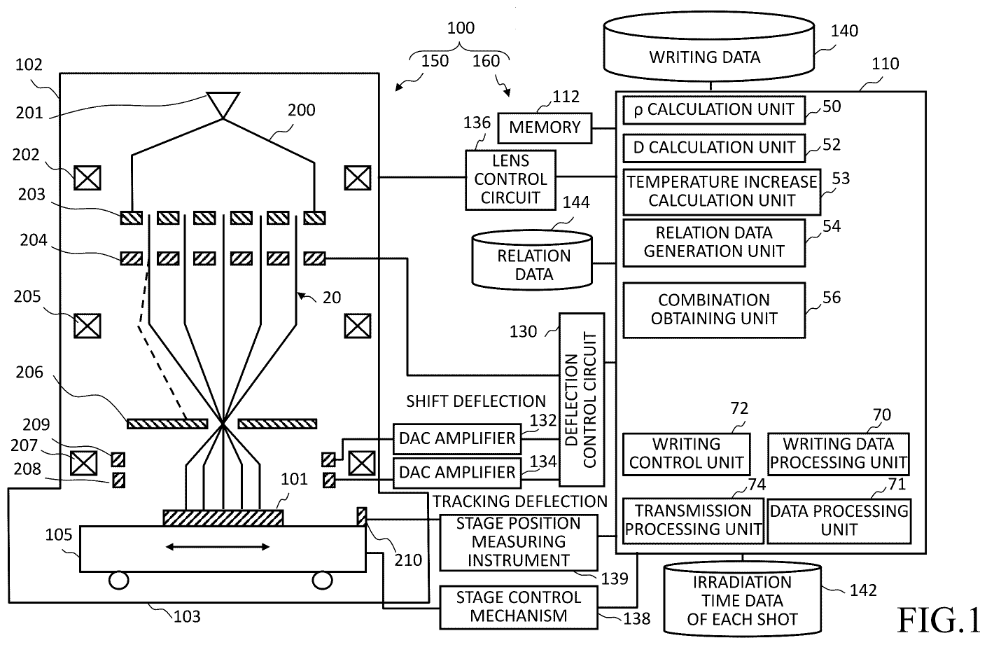

FIG. 1 is an illustration showing a schematic diagram of an example of a configuration of a writing or “drawing” apparatus according to a first embodiment. As shown in FIG. 1, a writing apparatus 100 includes a writing mechanism 150 and a control system circuit 160. The writing apparatus 100 is an example of a multiple charged particle beam writing apparatus and an example of a multiple charged particle beam exposure apparatus. The writing mechanism 150 includes an electron optical column 102 (electron beam column) and a writing chamber 103. In the electron optical column 102, an optical system for generating multiple charged particle beams and controlling their trajectories is configured, where there are disposed an electron gun 201, an illumination lens 202, a shaping aperture array substrate 203, a blanking aperture array mechanism 204, a reducing lens 205, a limiting aperture substrate 206, an objective lens 207, and deflectors 208 and 209.

In the writing chamber 103, an XY stage 105 is disposed. On the XY stage 105, there is placed a substrate 101 serving as a writing target substrate when writing (exposure) is performed. Resist has been applied on the substrate 101. For example, the substrate 101 is an exposure mask used in fabricating semiconductor devices, or a semiconductor substrate (silicon wafer) for fabricating semiconductor devices. Furthermore, the substrate 101 may be a mask blank on which nothing has yet been written. On the XY stage 105, a mirror 210 for measuring the position of the XY stage 105 is placed.

The control system circuit 160 includes a control computer 110, a memory 112, a deflection control circuit 130, digital-analog converter (DAC) amplifier units 132 and 134, a lens control circuit 136, a stage control mechanism 138, a stage position measuring instrument 139, and storage devices 140, 142 and 144 such as magnetic disk drives. The control computer 110, the memory 112, the deflection control circuit 130, the lens control circuit 136, the stage control mechanism 138, the stage position measuring instrument 139, and the storage devices 140, 142, and 144 are connected to each other through a bus (not shown). The DAC amplifier units 132 and 134 and the blanking aperture array mechanism 204 are connected to the deflection control circuit 130. The deflector 209 is composed of at least four electrodes (or “at least four poles”), and controlled by the deflection control circuit 130 through the DAC amplifier unit 132 disposed for each electrode. The deflector 208 is composed of at least four electrodes (or “at least four poles”), and controlled by the deflection control circuit 130 through the DAC amplifier unit 134 disposed for each electrode. Electron lenses (e. g., electromagnetic lenses or electrostatic lenses), such as the illumination lens 202, the reducing lens 205, and the objective lens 207, are controlled by the lens control circuit 136.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

In the control computer 110, there are arranged a pattern density (ρ) calculation unit 50, a dose (D) calculation unit 52, a temperature increase calculation unit 53, a relation data generation unit 54, a combination obtaining unit 56, a writing data processing unit 70, a data processing unit 71, a writing control unit 72, and a transmission processing unit 74.

Each of the “ . . . units” such as the pattern density calculation unit 50, the dose calculation unit 52, the temperature increase calculation unit 53, the relation data generation unit 54, the combination obtaining unit 56, the writing data processing unit 70, the data processing unit 71, the writing control unit 72, and the transmission processing unit 74 includes processing circuitry. The processing circuitry includes, for example, an electric circuit, a computer, a processor, a circuit board, a quantum circuit, a semiconductor device, or the like. Each “. . . unit” may use common processing circuitry (the same processing circuitry), or different processing circuitry (separate processing Information input/output to/from the pattern circuitry). density calculation unit 50, the dose calculation unit 52, the temperature increase calculation unit 53, the relation data generation unit 54, the combination obtaining unit 56, the writing data processing unit 70, the data processing unit 71, the writing control unit 72, and the transmission processing unit 74, and information being operated are stored in the memory 112 each time.

Writing operations of the writing apparatus 100 are controlled by the writing control unit 72. Processing of transmitting irradiation time data of each shot to the deflection control circuit 130 is controlled by the transmission processing unit 74.

Writing data (chip data) is input from the outside of the writing apparatus 100, and stored in the storage device 140. Chip data defines information on a plurality of figure patterns configuring a chip pattern. Specifically, for example, coordinates for each vertex are defined for each figure pattern in the order of configuration of the figure. Alternatively, for example, a figure code, coordinates, a size, and the like are defined for each figure pattern.

FIG. 1 shows a configuration necessary for describing the first embodiment. Other configuration elements generally necessary for the writing apparatus 100 may also be included therein.

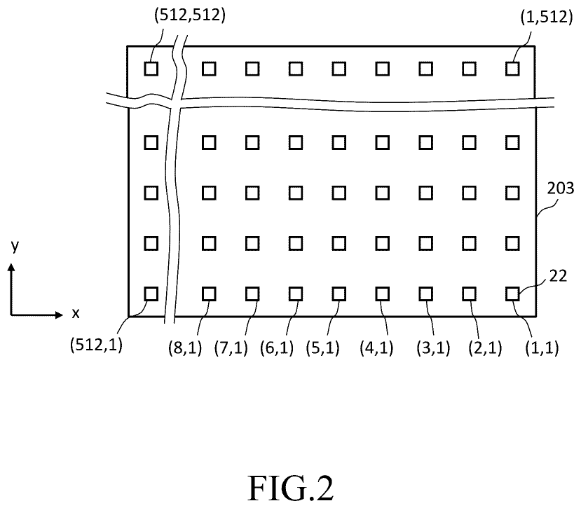

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes 22 of 512×512, that is 512 holes in the y direction and 512 holes in the x direction, are formed. The number of holes 22 is not limited thereto. For example, it is also preferable to form the holes 22 of 32×32. Each of the holes 22 is a rectangle (including square) having the same dimension and shape as each other. Alternatively, each of the holes 22 may be a circle with the same diameter as each other. The multiple beams 20 are formed by letting portions of an electron beam 200 individually pass through a corresponding one of a plurality of holes 22. In other words, the shaping aperture array substrate 203 forms the multiple beams 20.

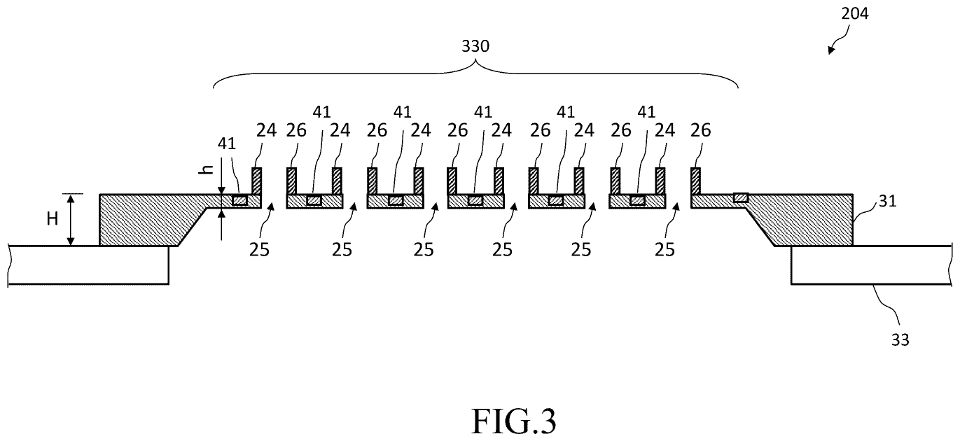

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed in the outer peripheral portion of the blanking aperture array substrate 31. The counter electrode 26 for each beam is grounded.

In the state where there is no potential difference between the potential of the control electrode 24 and the ground potential of the counter electrode 26, a corresponding beam is applied without being deflected. In the state where there is a potential difference between them, a blanking control is provided in order to generate a “beam OFF” state by deflecting a corresponding beam by an electric field, and blocking it by the limiting aperture substrate 206.

The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the deflectors 208 and 209 in order to irradiate respective beam irradiation positions on the substrate 101. For example, when the XY stage 105 is continuously moving, tracking control is performed by the deflector 208 so that the beam irradiation position may follow the movement of the XY stage 105.

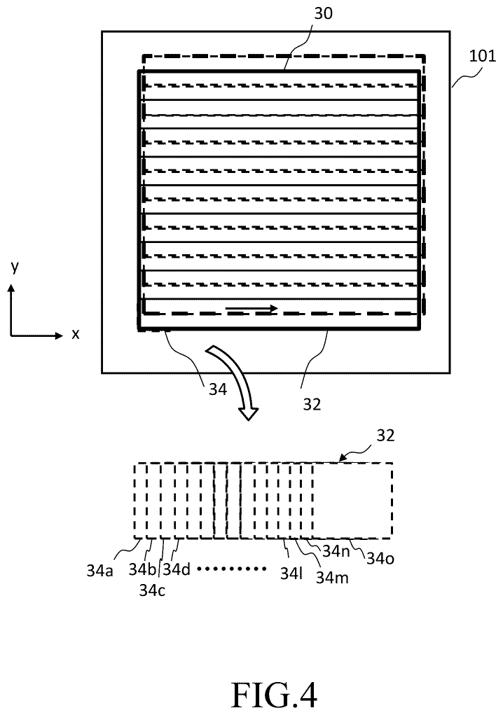

FIG. 4 is a conceptual diagram explaining an example of a writing region according to the first embodiment. As shown in FIG. 4, a writing region 30 (bold line) of the substrate 101 is virtually divided into a plurality of stripe regions 32 by a predetermined width in the y direction, for example. In the case of FIG. 4, the writing region 30 of the substrate 101 is divided in the y direction, for example, into a plurality of stripe regions 32 by the width size being substantially the same as the design size of an irradiation region 34 (writing field) that can be irradiated with one irradiation of the multiple beams 20. The x-direction design size of the irradiation region 34 of the multiple beams 20 can be defined by (the number of x-direction beams)×(beam pitch in the x direction). The y-direction size of the rectangular irradiation region 34 can be defined by (the number of y-direction beams)×(beam pitch in the y direction).

Furthermore, in the example of FIG. 4, a stripe layer composed of a plurality of stripe regions 32 obtained by dividing the writing region 30 is set.

Next, an example of the writing operation will be described. When the multiplicity is 1, (that is, when no multiple writing is performed), one stripe layer is formed. First, the XY stage 105 is moved to make an adjustment such that the irradiation region 34 of the multiple beams 20 is located at the left end, or at a position further left than the left end, of the first stripe region 32. Then, writing is performed to the first stripe region 32. When writing to the first stripe region 32, the XY stage 105 is moved, for example, in the −x direction, so that the writing may proceed relatively in the x direction. The XY stage 105 is moved, for example, continuously at a constant speed. After performing writing in the first stripe region 32, the stage position is moved in the −y direction by the shift amount of the width of the stripe region 32. Thereby, the stripe region 32 to be written is shifted in the y direction by the width of the stripe region 32.

Next, an adjustment is made so that the irradiation region 34 of the multiple beams 20 can be located at the left end, or at a position further left than the left end, of the second stripe region 32. Then, by moving the XY stage 105 in the −x direction, for example, writing proceeds relatively in the x direction. Thereby, writing is performed to the second stripe region 32. Henceforth, writing proceeds in the same way. Thus, writing is performed to the k-th stripe region 32 during one movement in the −x direction of the XY stage 105.

When the multiplicity is 2, (that is, when two-time multiple writing is performed), the first stripe layer for the first writing processing and the second stripe layer for the second writing processing are formed. The first stripe layer and the second stripe layer are formed to be shifted from each other by, in the y direction, ½ of the width of the stripe region 32. The contents of the writing processing of the first stripe region 32 of the first stripe layer are the same as those described above. After performing writing in the first stripe region 32 of the first stripe layer, the stage position is moved in the −y direction by the shift amount of ½ of the width of the stripe region 32. Thereby, the stripe region 32 to be written is moved from the first stripe region 32 of the first stripe layer to the first stripe region 32 of the second stripe layer.

Next, an adjustment is made so that the irradiation region 34 of the multiple beams 20 can be located at the left end, or at a position further left than the left end, of the first stripe region 32 of the second stripe layer. Then, by moving the XY stage 105 in the −x direction, for example, writing proceeds relatively in the x direction. Thereby, writing is performed to the first stripe region 32 of the second stripe layer. Thus, multiple writing of multiplicity being 2 has been performed to the upper half of the first stripe region 32 of the first stripe layer (the lower half of the first stripe region 32 of the second stripe layer).

After performing writing in the first stripe region 32 of the second stripe layer, the stage position is moved in the −y direction by the shift amount of ½ of the width of the stripe region 32. Thereby, the stripe region 32 to be written is moved from the first stripe region 32 of the second stripe layer to the second stripe region 32 of the first stripe layer. Henceforth, writing proceeds in the same way.

For example, when the multiplicity is 4, (that is, when four-time multiple writing is performed), the first stripe layer for the first writing processing, the second stripe layer for the second writing processing, the third stripe layer for the third writing processing, and the fourth stripe layer for the fourth writing processing are formed. The first stripe layer, the second stripe layer, the third stripe layer and the fourth stripe layer are formed to be mutually shifted from each other by, in the y direction, ¼ of the width of the stripe region 32. By performing writing while shifting, in the y direction, the stripe region of each stripe layer by ¼ of the width of the stripe region 32, four-time multiple writing is performed.

As described above, it is also preferable to perform multiple writing such that the stage moves on the same position a plurality of times. In that case, preferably, the multiple writing is performed while shifting the position in the y direction by the shift amount of 1/n of the width of the stripe region, for example. It is also acceptable to perform multiple writing overlappingly without shifting the position of the stripe region.

In the examples described above, while writing is performed to one stripe region of one stripe layer during one stage movement (one pass) in the −x direction, respective positions in the stripe region concerned are individually written once. However, the method of multiple writing is not limited thereto. Respective positions in the stripe region concerned may be written a plurality of times during one pass.

For example, it is also acceptable that the first writing is performed with beams in the right half in the x direction of the multiple beams 20, and the second writing is performed to the same positions with left half beams. For easily understanding the description, the case where respective positions in the stripe region concerned are written once with one pass will be explained.

FIG. 4 shows the case where each stripe region 32 is written in the same direction, but, it is not limited thereto. For example, with respect to the stripe region 32 to be written following the stripe region 32 having already been written in the x direction, it may be written in the −x direction by moving the XY stage 105 in the x direction, for example. Thus, due to performing writing while alternately changing the writing direction, the writing time can be reduced.

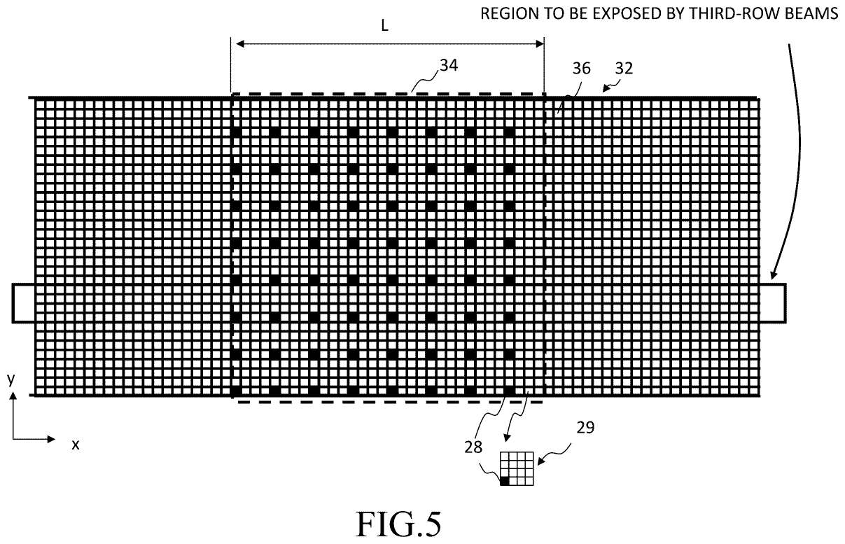

FIG. 5 is an illustration showing an example of a multiple beam array according to the first embodiment. FIG. 5 shows the case of 8×8 multiple beams 20, for example. The x-direction beam array size L is defined by a value obtained by multiplying the x-direction beam pitch by the number of x-direction beams. The y-direction beam array size L is defined by a value obtained by multiplying the y-direction beam pitch by the number of y-direction beams. The region surrounded by the x-direction beam array size L and the y-direction beam array size L serves as the irradiation region 34 of multiple beams. In the example of FIG. 5, the beam pitch is the distance composed of four pixels 36, for example. A sub-irradiation region 29 of each beam 28 of the multiple beams 20 is a region surrounded by the x-direction beam pitch and the y-direction beam pitch. In the case of FIG. 5, the sub-irradiation region 29 is composed of 4×4 pixels.

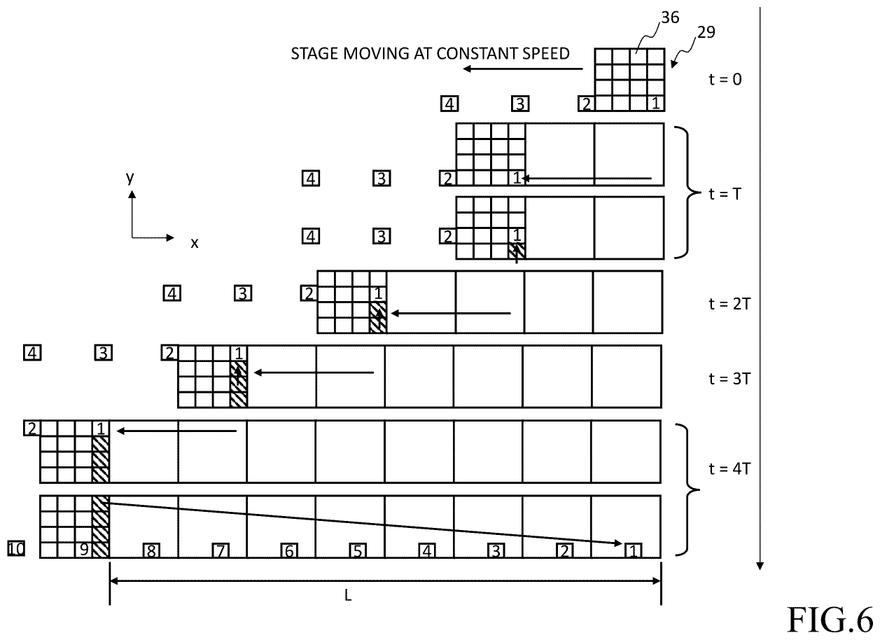

FIG. 6 is an illustration explaining an example of a multiple beam writing operation according to the first embodiment. FIG. 6 shows the case where the inside of each sub-irradiation region 29, which includes the beam irradiation position of one of the multiple beams 20 and is surrounded by the beam pitch (pitch between beams), is written with four different beams. The example of FIG. 6 shows a writing operation where the XY stage 105 continuously moves at the speed at which the XY stage 105 moves the distance of eight beam pitches while writing a ¼ region, namely the region of 1/(the number of beams used for irradiation), in each sub-irradiation region 29. FIG. 6 shows the case where each sub-irradiation region 29 is composed of 4×4 pixels, for example.

In the writing operation shown in FIG. 6, for example, while the XY stage 105 moves the distance of eight beam pitches in the x direction, four different pixels 36 in the same sub-irradiation region 29 are written (exposed) by applying four shots of the multiple beams 20 at a shot cycle with sequentially shifting the irradiation position (pixel 36) by the deflector 209. In order that the relative position between the irradiation region 34 and the substrate 101 may not be displaced by the movement of the XY stage 105 while the four pixels 36 are written (exposed), the irradiation region 34 is made to follow the movement of the XY stage 105 by collective deflection of all of the multiple beams 20 by the deflector 208. In other words, a tracking control is performed. After one tracking cycle is completed, tracking is reset to return to the previous (last) tracking starting position. Since writing of the pixels in the first column from the right of each sub-irradiation region 29 has been completed, in the next tracking cycle after resetting the tracking, first, the deflector 209 provides deflection such that the writing position of a beam is adjusted (shifted) to write the second pixel column from the right which has not yet been written in each sub-irradiation region 29, for example. By repeating this operation during performing writing in the stripe region 32, as shown in the lower part of FIG. 4, the position of the irradiation region 34 (34a to 34o) of the multiple beams 20 is sequentially moved (shifted) to perform writing.

During the next tracking control after resetting the tracking, four pixels in the same sub-irradiation region are to be written with another beam which is, for example, eight sub-irradiation regions 29 away in the x direction. By performing the tracking control four times, one writing processing is completed to all the pixels in each sub-irradiation region with four different beams. Therefore, in the case where the sub-irradiation region 29 is composed of 4×4 pixels and a writing operation is performed such that four shots are applied during one tracking control of making a movement of eight beam pitches, one writing processing is performed to the substrate 101 with 32 (=4×8) beams in the x direction in each of rows arrayed in the y direction. In the case where the sub-irradiation region 29 is composed of 16×16 pixels, and a writing operation is performed such that eight shots are applied during one tracking control of making a movement of sixteen beam pitches, one writing processing is performed to the substrate 101 with 512 (=32×16) beams in the x direction in each of rows arrayed in the y direction. Multiple writing is executed by moving the XY stage 105 a plurality of times to repeat writing to the same stripe region 32 with multiple beams necessary for single writing processing as described above.

In the case where the sub-irradiation region 29 is composed of 4×4 pixels and a writing operation is performed such that four shots are applied during one tracking control of making a movement of eight beam pitches, it is also preferable to perform multiple writing during one pass. For example, when the multiple beams 20 is composed of 64 beams in the x direction and the writing operation described above is performed, multiple writing of multiplicity being 2 can be executed during one pass. By arranging more beams in the x direction, the multiplicity can further be increased.

As described above, due to increase of temperature of resist applied on the substrate 101, a problem may occur such as uncorrectable degradation of pattern CD (critical dimension) accuracy, or alteration of resist. In order to cope with this problem, it is necessary to suppress increase of temperature of the substrate generated by writing processing.

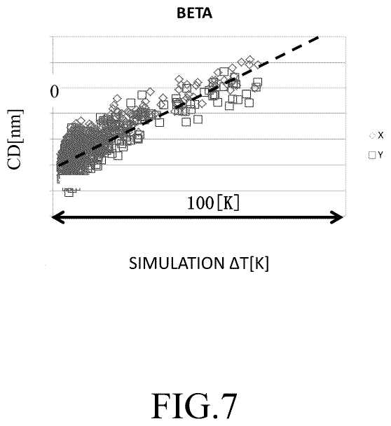

FIG. 7 is an illustration showing an example of a relationship between a resist temperature increase and pattern dimension according to the first embodiment. In FIG. 7, the ordinate axis represents a pattern dimension (CD), and the abscissa axis represents a simulated temperature increase ΔT. It turns out in the example of FIG. 7 that the pattern dimension (CD) becomes large along with increase of temperature of resist. Furthermore, in the range where a resist temperature increase ΔT (relative temperature) increased from a normal temperature (e.g., 20° C.) is 100K or less, the temperature increase and the CD can be approximated in order to have a linear (linear proportion) change. Therefore, as long as the resist temperature increase is within the range, the CD can be corrected when writing is performed. Accordingly, in order to make dimension accuracy of a writing pattern allowable, it is necessary to suppress a resist temperature increase ΔT (relative temperature) to be 100K or less which is a temperature increase making CD correctable.

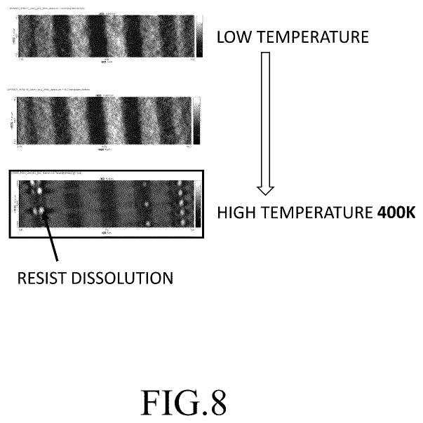

FIG. 8 is an illustration showing an example of a relation between increase of temperature of resist and alteration of the resist according to the first embodiment. As shown in FIG. 8, when the resist temperature increase ΔT (relative temperature) increased from a normal temperature (e.g., 20° C.) reaches 400K, the resist begins to dissolve. Therefore, in order to inhibit the resist dissolution, the resist temperature increase ΔT (relative temperature) needs to be suppressed to be lower than 400K, such as 300K.

The temperature of the resist can be regarded substantially the same as that of the substrate 101.

In order to suppress the temperature increase of the resist (the temperature increase of the substrate 101), it is effective to decrease the dose for each writing processing of multiple writing, to increase the multiplicity, and/or to reduce the stage speed. However, if these measures are performed excessively, it causes a problem that the writing time increases more than needed and the throughput degrades to be less than needed. Then, according to the first embodiment, the multiplicity and the stage speed are obtained such that the writing time can be as short as possible in the range where no uncorrectable CD accuracy degradation occurs or no resist alteration occurs. The details are explained below.

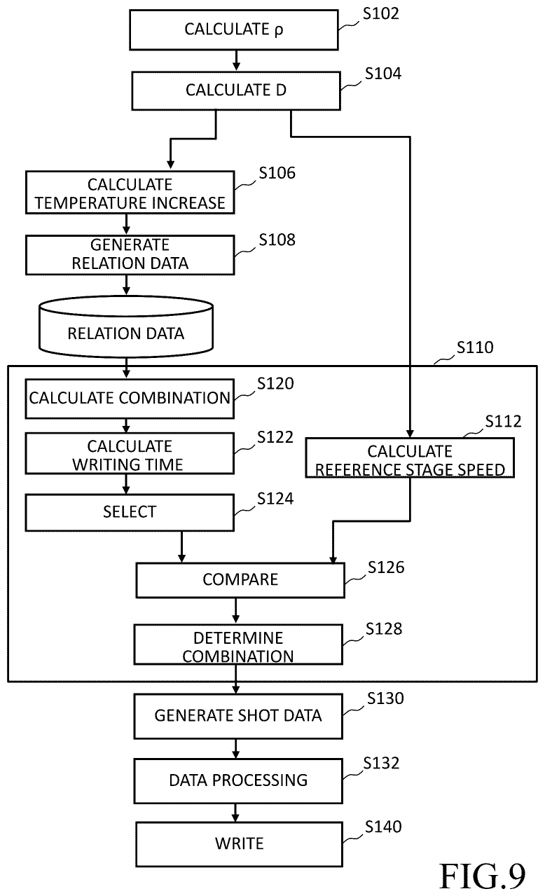

FIG. 9 is a flowchart showing an example of main steps of a writing method according to the first embodiment. In FIG. 9, the writing method of the first embodiment executes a series of steps: a pattern density calculation step (S102), a dose calculation step (S104), a temperature increase calculation step (S106), a relation data generation step (S108), a combination obtaining step (S110), a shot data generation step (S130), a data processing step (S132), and a writing step (S140). The combination obtaining step (S110) executes, as internal steps, a reference stage speed calculation step (S112), a combination calculation step (S120), a writing time calculation step (S122), a selection step (S124), a comparison step (S126), and a combination determination step (S128).

In the pattern density calculation step (S102), the pattern density calculation unit 50 reads writing data from the storage device 140, and calculates, for each pixel 36, a pattern density ρ (area density) of the pixel 36 concerned. This processing is performed for each stripe region 32, for example.

In the dose calculation step (S104), the dose calculation unit 52, first, virtually divides the writing region (e.g., in this case, stripe region 32) into a plurality of proximity mesh regions (mesh regions for proximity effect correction calculation) by a predetermined size. The size of the proximity mesh region is preferably set to be about 1/10 of the influence range of the proximity effect, such as about 1 μm. The dose calculation unit 52 reads writing data from the storage device 140, and calculates, for each proximity mesh region, a pattern area density ρ″ of a pattern arranged in the proximity mesh region concerned.

Next, the dose calculation unit 52 calculates, for each proximity mesh region, a proximity effect correction irradiation coefficient Dp(x) (correction dose) for correcting a proximity effect. An unknown proximity effect correction irradiation coefficient Dp(x) can be defined by a threshold value model for proximity effect correction, which is the same as the one used in a conventional method, where a backscatter coefficient n, a dose threshold value Dth of a threshold value model, a pattern area density ρ″, and a distribution function g(x) are used.

Then, the dose calculation unit 52 calculates, for each pixel 36, a dose D (incident dose) with which the pixel 36 concerned is irradiated. The dose D can be calculated, for example, by multiplying a base dose Dbase, a proximity effect correction irradiation coefficient Dp, and a pattern density ρ′. The base dose Dbase can be defined by Dth/(½+η), for example. Then, a dose map is generated by mapping the dose D of each pixel.

In the temperature increase calculation step (S106), the temperature increase calculation unit 53 calculates a maximum temperature increase ΔTₘₐₓ of the resist by using with varying a total dose D₀ of the irradiation region 34 of the multiple beams 20 and a stage speed V_{stage}.

In each of a plurality of mesh regions obtained by dividing the writing region to be irradiated with the multiple beams 20, the temperature increase of the resist is calculated, for example, based on a representative value of the dose of a beam applied to the mesh region concerned, a stage speed, and a size in a writing movement direction of the irradiation region of the multiple beams 20.

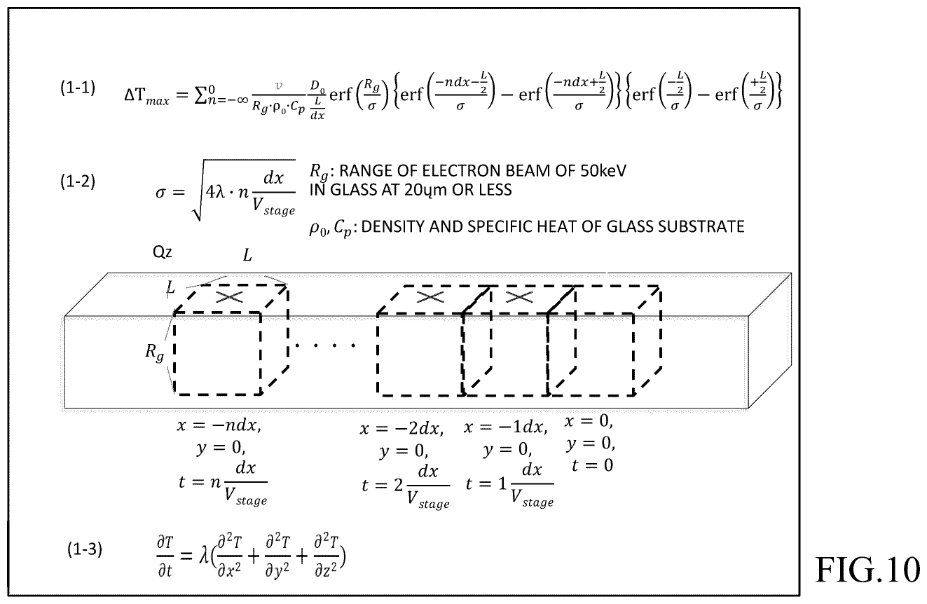

FIG. 10 is an illustration showing an example of a resist temperature increase model according to the first embodiment. In the temperature increase model in FIG. 10, it is assumed that, when x=0, y=0, and t=0, the irradiation region 34 of the multiple beams 20 having a size of L×L is irradiated with a solid pattern (or “beta pattern”), based on an electron beam of acceleration voltage v, a total dose D₀, and a stage speed V_{stage}. The maximum temperature increase ΔTₘₐₓ at this time is defined, with respect to the position (x=0, y=0), by a value obtained by adding heat transfer temperatures due to irradiation energy up to the n-th previous tracking cycle. By setting n as infinity ∞, the maximum temperature increase ΔTₘₐₓ in this case can be defined by the equation (1-1) in FIG. 10. The equation (1-1) can be solved under the initial condition of the case where a uniform heat is applied, with beam irradiation, to the cube obtained by multiplying the mesh size of the substrate surface by R_{g}. In the equation (1-1), R_{g} indicates a range of an electron beam of 50 kV in quartz. The term with respect to each n can be solved by the equation (1-3) in FIG. 10 being a general thermal diffusion equation. λ, in this case, indicates a thermal diffusivity of the substance which diffuses temperatures. ndx indicates the position in the x direction of the irradiation region 34 of the multiple beams 20, at the n-th previous tracking cycle, with respect to the position x=0. Furthermore, the function σ of the equation (1-1) can be defined by the equation (1-2) in FIG. 10. The maximum temperature increase ΔTₘₐₓ in the combination of the total dose D₀ of the irradiation region 34 of the multiple beams 20 and the stage speed V_{stage} is calculated with varying the total dose D₀ and the stage speed V_{stage}.

In the relation data generation step (S108), using a calculated maximum temperature increase ΔTₘₐₓ of the resist, the relation data generation unit 54 generates relation data among a stage speed V_{stage} of the stage on which the substrate coated with the resist is to be placed, a dose D for each writing processing of multiple writing, and a temperature increase ΔT of the resist. As the temperature increase ΔT of the resist, a calculated maximum temperature increase ΔTₘₐₓ of the resist is used.

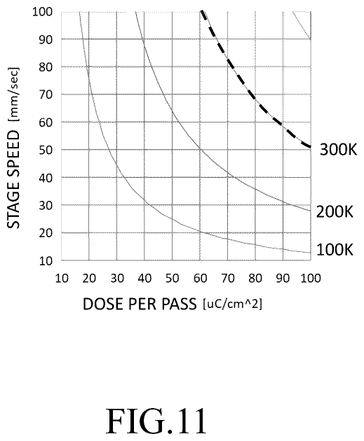

FIG. 11 is an illustration showing an example of relation data according to the first embodiment. In FIG. 11, the ordinate axis represents a stage speed, and the abscissa axis represents a dose D for each writing processing of multiple writing. Related graphs are shown for every resist maximum temperature increase ΔTₘₐₓ. FIG. 11 shows a relation between a stage speed V_{stage} and a dose D for each writing processing in multiple writing in the cases of resist maximum temperature increases ΔTₘₐₓ of 100K, 200K, and 300K.

Generated relation data is stored in the storage device 144. Although, in the example described above, the relation data is generated in the writing apparatus 100, it is not limited thereto. After relation data is generated off-line, it may be input into the writing apparatus 100 to be stored in the storage device 144.

In the combination obtaining step (S110), the combination obtaining unit 56 reads relation data from the storage device 144, for example, and obtains, using the read relation data, a combination of a stage speed V_{stage} at which writing can be performed in the range where a resist temperature increase is within an allowable temperature increase, and multiplicity N of multiple writing.

Specifically, it operates as follows:

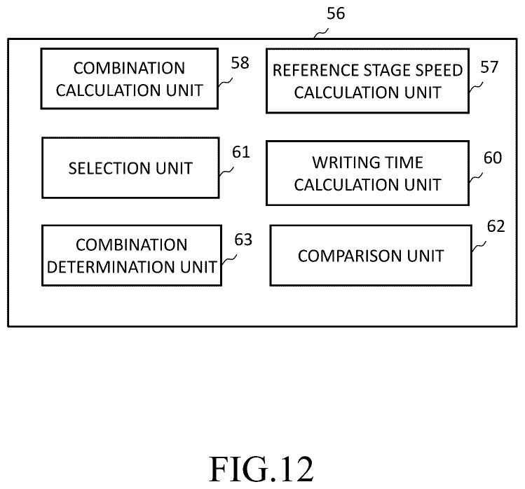

FIG. 12 is a block diagram showing an example of the internal configuration of a combination obtaining unit according to the first embodiment. In FIG. 12, in the combination obtaining unit 56, there are arranged a reference stage speed calculation unit 57, a combination calculation unit 58, a writing time calculation unit 60, a selection unit 61, a comparison unit 62, and a combination determination unit 63. Therefore, each of the “ . . . units” such as the pattern density calculation unit 50, the dose calculation unit 52, the temperature increase calculation unit 53, the relation data generation unit 54, the combination obtaining unit 56 (the reference stage speed calculation unit 57, the combination calculation unit 58, the writing time calculation unit 60, the selection unit 61, the comparison unit 62, and the combination determination unit 63), the writing data processing unit 70, the data processing unit 71, the writing control unit 72, and the transmission processing unit 74 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the pattern density calculation unit 50, the dose calculation unit 52, the temperature increase calculation unit 53, the relation data generation unit 54, the combination obtaining unit 56 (the reference stage speed calculation unit 57, the combination calculation unit 58, the writing time calculation unit 60, the selection unit 61, the comparison unit 62, and the combination determination unit 63), the writing data processing unit 70, the data processing unit 71, the writing control unit 72, and the transmission processing unit 74, and information being operated are stored in the memory 112 each time.

In the reference stage speed calculation step (S112), the reference stage speed calculation unit 57 calculates a reference stage speed V₀at which writing can be performed. As the reference stage speed V₀, calculated is the maximum stage speed in the range where writing processing is executable. Therefore, if writing processing is performed at a speed exceeding the reference stage speed V₀, it becomes an error because the processing of writing cannot keep up with the speed. The reference stage speed calculation unit 57 specifies, based on a generated dose map, the maximum dose for a chip region unit to be written. The irradiation time (the maximum irradiation time) of the maximum dose is calculated by dividing the maximum dose by a current density. Then, a value obtained by adding a settling time to the maximum irradiation time serves as a shot cycle. A value obtained by multiplying a shot cycle by the number of shots, k, during one tracking control serves as a tracking cycle. Therefore, for example, in the case where the multiplicity of writing sequence is N (N being a natural number) and k shots are continuously applied to each sub-irradiation region 29 during a movement of m beam pitches, the reference stage speed calculation unit 57 calculates a reference stage speed V₀ by dividing the distance of m beam pitches by {(maximum irradiation time/N+settling time)×k}. For example, in the case where the multiplicity of writing sequence is two (N being a natural number) and four shots are continuously applied to each sub-irradiation region 29 during a movement of eight beam pitches, the reference stage speed calculation unit 57 calculates a reference stage speed V₀ by dividing the distance of eight beam pitches by {(maximum irradiation time/2+settling time)×4}. Here, the reference stage speed V₀ at each multiplicity is calculated with varying the multiplicity N, for example. Data of the calculated reference stage speed V₀ at each multiplicity is stored in the storage device 144.

### Case 1

Case 1 describes, with regard to a combination of the stage speed V_{stage} and the multiplicity N, the case where the multiplicity N has been preset. In Case 1, an allowable temperature increase, a resist sensitivity, and multiplicity (here, i.e., the number of passes) are input as parameters.

Using relation data, the combination obtaining unit 56 obtains the maximum stage speed V_{stage} at which writing can be performed within an allowable temperature increase, depending on a preset multiplicity N and a resist exposure sensitivity. The details are explained below.

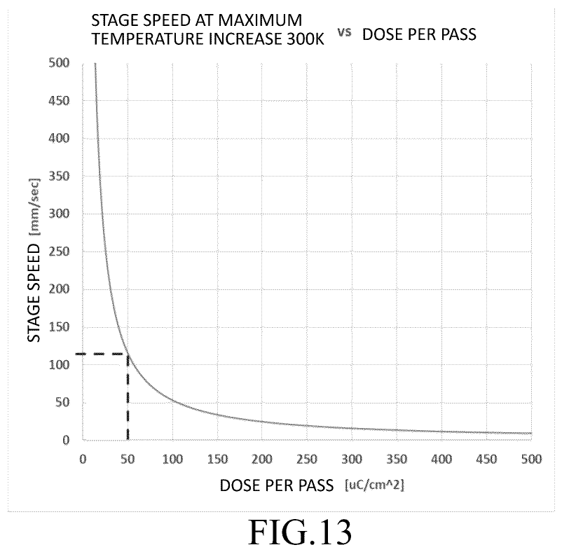

FIG. 13 is an illustration showing an example of a relation between a stage speed V_{stage} at an allowable temperature increase and a dose D for each writing processing in multiple writing according to the first embodiment. In FIG. 13, the ordinate axis represents a stage speed V_{stage}, and the abscissa axis represents a dose for each writing processing.

In the case of intending to avoid alteration of resist, a temperature increase (e.g., 300K) of the resist having a temperature less than a resist dissolving temperature is used as an allowable temperature increase. Alternatively, in the case of intending to avoid uncorrectable CD accuracy degradation, a temperature increase (e.g., 100K) at which dimension accuracy of a writing pattern is allowable is used as an allowable temperature increase. In the example of FIG. 13, 300K is used as the allowable temperature increase. The example of FIG. 13 describes the case where the multiplicity N=2 has previously been set, and a sensitivity of resist is 100 μC/cm², for example.

In the case of FIG. 13, referring to the relation data shown in FIG. 11, the combination obtaining unit 56, first, extracts a graph whose maximum temperature increase is 300K. In the combination calculation step (S112), using the relation data, the combination calculation unit 58 calculates the maximum stage speed V_{stage} within an allowable temperature increase, depending on a preset multiplicity N and a resist exposure sensitivity. In the example of FIG. 13, since N=2, the dose for each writing processing is 50 μC/cm² being ½ of resist sensitivity. Therefore, referring to the relation data, the combination calculation unit 58 calculates the stage speed V_{stage}, corresponding to the case where the dose for each writing processing is 50 μC/cm², to be 120 mm/sec, for example.

In Case 1, since the multiplicity has previously been set, no writing time is compared depending on the difference between multiplicities. Therefore, the writing time calculation step (S122) and the selection step (S124) are omitted.

In the comparison step (S126), the comparison unit 62 compares a calculated stage speed V_{stage} with a reference stage speed V₀ at the preset multiplicity.

In the combination determination step (S128), when the comparison result is that the calculated stage speed V_{stage} is equal to or less than the reference stage speed V₀ at the preset multiplicity, the combination determination unit 63 determines the combination of the preset multiplicity and the calculated stage speed V_{stage} to be a combination used as writing conditions. If the calculated stage speed V_{stage} is faster than the reference stage speed V₀ at the preset multiplicity, the combination determination unit 63 determines the combination of the preset multiplicity and the reference stage speed V₀ to be a combination used as writing conditions. This is because when the stage speed is faster than the reference stage speed V₀, the processing of writing cannot keep up with the speed, and writing is not fulfilled.

Thereby, it is possible to obtain a combination of the maximum stage speed V_{stage} at which writing can be performed in the range where a resist temperature increase is within an allowable temperature increase, and the multiplicity N of multiple writing.

### Case 2

Case 2 describes the case of obtaining one combination out of a plurality of combinations each composed of the stage speed V_{stage} and the multiplicity N. In Case 2, an allowable temperature increase, a resist sensitivity, the maximum stage speed which the writing apparatus 100 can mechanically generate, and the minimum stage speed are input as parameters.

The combination obtaining unit 56 obtains, using relation data, a combination of the stage speed V_{stage}, at which writing can be performed within an allowable temperature increase and the writing time is shortest, and the multiplicity, depending on the multiplicity N and the resist exposure sensitivity. The details are explained below.

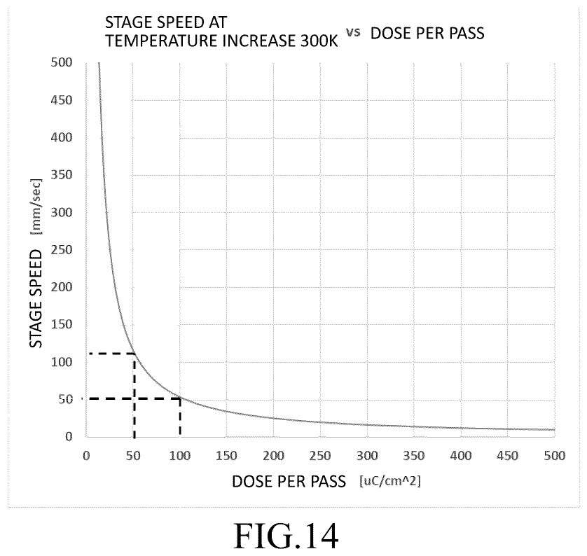

FIG. 14 is an illustration showing an example of a relation between a stage speed V_{stage} at an allowable temperature increase and a dose D for each writing processing in multiple writing, and an example of a dose for each multiplicity according to the first embodiment. In FIG. 14, the ordinate axis represents a stage speed V_{stage}, and the abscissa axis represents a dose for each writing processing. In Case 2, similarly to Case 1, 300K is used as the allowable temperature increase. The example of FIG. 14 describes the case where a sensitivity of resist is 100 μC/cm², for example.

In the case of FIG. 14, referring to the relation data shown in FIG. 11, the combination obtaining unit 56, first, extracts a graph whose maximum temperature increase is 300K.

In the combination calculation step (S120), using relation data, the combination calculation unit 58 calculates a plurality of combinations each composed of a stage speed V_{stage} and multiplicity N, depending on a resist exposure sensitivity. The example of FIG. 14 shows the cases of the multiplicity being N=1 (one pass) and the multiplicity being N=2 (two passes). In the case of FIG. 14, when N=1, for example, the dose for each writing processing is 100 μC/cm² being a sensitivity of resist. Therefore, referring to relation data, the combination calculation unit 58 calculates a stage speed V_{stage} corresponding to the case where the dose for each writing processing is 100 μC/cm², to be 50 mm/sec, for example. When N=2, for example, the dose for each writing processing is 50 μC/cm² being ½ of the sensitivity of resist. Therefore, referring to the relation data, the combination calculation unit 58 calculates a stage speed V_{stage} corresponding to the case where the dose for each writing processing is 50 μC/cm², to be 120 mm/sec, for example. When N=4, for example, the dose for each writing processing is 25 μC/cm² being ¼ of the sensitivity of resist. Therefore, referring to the relation data, the combination calculation unit 58 calculates a stage speed V_{stage} corresponding to the case where the dose for each writing processing is 25 μC/cm², to be 250 mm/sec, for example. When the maximum stage speed which the writing apparatus 100 can mechanically generate is 200 mm/sec, for example, the case of the multiplicity 4 is excluded. When the minimum stage speed which the writing apparatus 100 can mechanically generate is 20 mm/sec, for example, since the cases of the multiplicities 1 and 2 are in the range of generation, they are maintained.

Furthermore, it is preferable for the combination calculation unit 58 to calculate, while varying the sensitivity of resist, a plurality of combinations each composed of a stage speed V_{stage} and multiplicity N at each resist sensitivity.

In the writing time calculation step (S122), the writing time calculation unit 60 calculates a writing time in the case of performing writing under writing conditions of each obtained combination. For example, the writing time calculation unit 60 calculates a writing time by adding a time T of moving the XY stage 105 along the length of the stripe region 32 at the stage speed of each combination and a stage moving time to the next stripe region, and then, by multiplying the added value by the number of stripe regions per chip region, and the multiplicity.

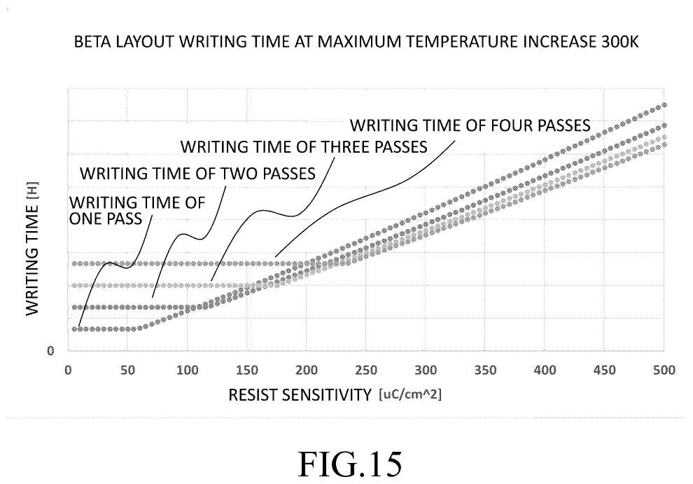

FIG. 15 is an illustration showing an example of a relation among a writing time, a resist sensitivity, and multiplicity according to the first embodiment. In FIG. 15, the ordinate axis represents a writing time, and the abscissa axis represents a resist sensitivity. FIG. 15 shows the cases of writing of multiplicity being 1 (one pass), multiplicity being 2 (two passes), multiplicity being 3 (three passes), and multiplicity being 4 (four passes). As shown in FIG. 15, depending on the sensitivity of resist, there is a case where the writing time of the case of multiplicity 2 (two passes), multiplicity 3 (three passes), or multiplicity 4 (four passes) is shorter than that of multiplicity 1 (one pass). Similarly, depending on the sensitivity of resist, there is a case where the writing time of the case of multiplicity 3 (three passes) or multiplicity 4 (four passes) is shorter than that of multiplicity 2 (two passes). Similarly, depending on the sensitivity of resist, there is a case where the writing time of the case of multiplicity 4 (four passes) is shorter than that of multiplicity 3 (three passes).

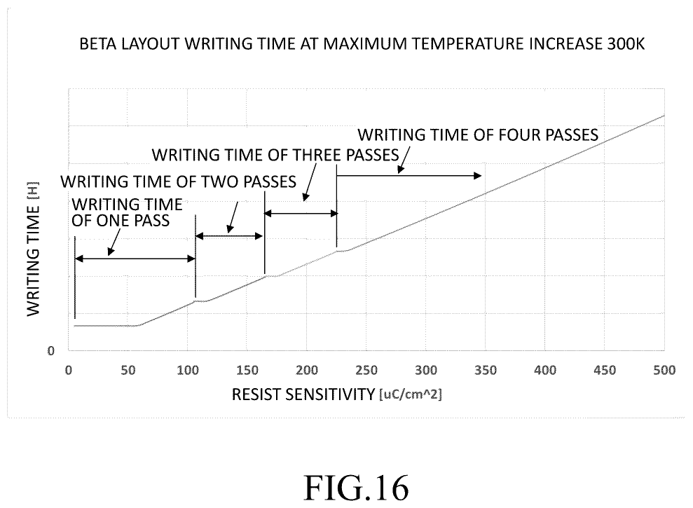

FIG. 16 is an illustration showing another

example of a relation among a writing time, a resist sensitivity, and multiplicity according to the first embodiment. FIG. 16 shows the multiplicity of the shortest writing time depending on a sensitivity of resist. In FIG. 16, it turns out that, in the range of resist sensitivity being 0 to 110 μC/cm², for example, the writing time is shortest in the case of writing of multiplicity 1 (one pass). It turns out that, in the range of resist sensitivity being 110 to 170 μC/cm², for example, the writing time is shortest in the case of writing of multiplicity 2 (two passes). It turns out that, in the range of resist sensitivity being 170 to 225 μC/cm², for example, the writing time is shortest in the case of writing of multiplicity 3 (three passes). It turns out that, in the range of resist sensitivity being greater than 225 μC/cm², for example, the writing time is shortest in the case of writing of multiplicity 4 (four passes).

In the selection step (S124), the selection unit 61 inputs, out of a plurality of calculated combinations, a sensitivity of resist applied on the target substrate 101, and selects, out of the plurality of combinations, a combination of the stage speed V and the multiplicity N according to which the writing time is shortest at the resist sensitivity concerned. Since the resist sensitivity is 100 μC/cm², for example, in the example of FIG. 14, the writing time is shortest in the case of multiplicity 1 (pass 1) according to the graph of FIG. 16. Therefore, the selection unit 61 selects the combination of the multiplicity 1 (pass 1) and the stage speed 120 mm/sec.

In the comparison step (S126), the comparison unit 62 compares a selected stage speed V_{stage} and a reference stage speed V₀ at a selected multiplicity.

In the combination determination step (S128), when the comparison result is that a calculated stage speed V_{stage} is equal to or less than the reference stage speed V₀ at a selected multiplicity, the combination determination unit 63 determines the combination of the selected multiplicity and the calculated stage speed V_{stage} to be a combination used as writing conditions. If the calculated and selected stage speed V_{stage} is faster than the reference stage speed V₀, the combination determination unit 63 determines the combination of the selected multiplicity and the reference stage speed V₀ to be a combination used as writing conditions. This is because when the stage speed is faster than the reference stage speed V₀, the processing of writing cannot keep up with the speed, and writing is not fulfilled.

Thereby, it is possible to obtain a combination of the maximum stage speed V_{stage} at which writing can be performed in the range where a resist temperature increase is within an allowable temperature increase, and the multiplicity N of multiple writing.

In the shot data generation step (S130), the writing data processing unit 70 calculates, using a dose map, an irradiation time for ach pixel 36. The irradiation time for each pixel 36 can calculated by dividing a dose (incident dose) D of the pixel concerned by a current density J.

In the data processing step (S132), the data processing unit 71 rearranges obtained irradiation time data for each pixel 36 in the order of shots, and stores it in the storage device 142. The transmission processing unit 74 transmits irradiation time data to the deflection control circuit 130 in the order of shots.

In the writing step (S140), under the control of the writing control unit 76, the writing mechanism 150 writes a pattern with the multiple beams 20 onto the substrate 101 placed on the XY stage 105 through writing processing in accordance with an obtained combination of the stage speed V_{stage} and the multiplicity N.

As described above, according to the first embodiment, it is possible to obtain writing conditions which suppress a writing time increase in the range where no uncorrectable CD accuracy degradation occurs or no resist alteration (deterioration) occurs. Furthermore, it is possible to easily obtain, in the writing apparatus 100, multiplicity and a stage speed which can suppress a writing time increase.

### Second Embodiment

A second embodiment describes a configuration in which the cases 1 and 2 described above are combined and it is possible to select not to perform writing. The configuration of the writing apparatus according to the second embodiment is the same as that of FIG. 1. Hereinafter, what is not particularly described is the same as that of the first embodiment.

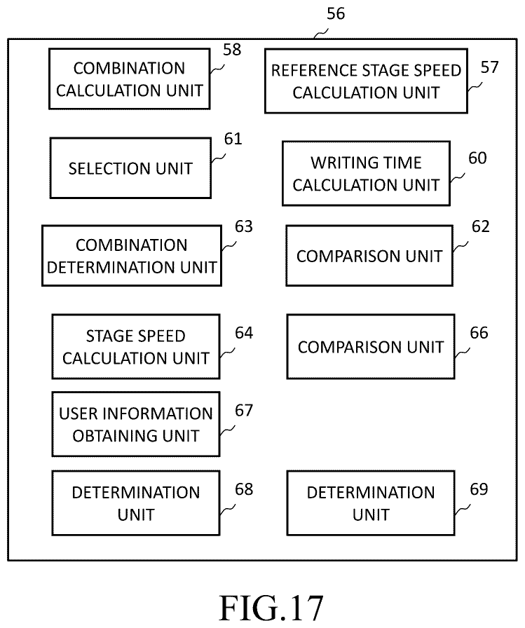

FIG. 17 is a block diagram showing an example of an internal configuration of the combination obtaining unit according to the second embodiment. FIG. 17 is the same as FIG. 12 except that a stage speed calculation unit 64, a comparison unit 66, a user information obtaining unit 67, a determination unit 68, and a determination unit 69 are further added in the combination obtaining unit 56. The combination obtaining unit 56 (or control computer 110) and the storage device 144 are examples of a stage speed obtaining apparatus. Each of the “ . . . units” such as the pattern density calculation unit 50, the dose calculation unit 52, the temperature increase calculation unit 53, the relation data generation unit 54, the combination obtaining unit 56 (the reference stage speed calculation unit 57, the combination calculation unit 58, the writing time calculation unit 60, the selection unit 61, the comparison unit 62, the combination determination unit 63, the stage speed calculation unit 64, the comparison unit 66, the user information obtaining unit 67, the determination unit 68, and the determination unit 69), the writing data processing unit 70, the data processing unit 71, the writing control unit 72, and the transmission processing unit 74 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the pattern density calculation unit 50, the dose calculation unit 52, the temperature increase calculation unit 53, the relation data generation unit 54, the combination obtaining unit 56 (the reference stage speed calculation unit 57, the combination calculation unit 58, the writing time calculation unit 60, the selection unit 61, the comparison unit 62, the combination determination unit 63, the stage speed calculation unit 64, the comparison unit 66, the user information obtaining unit 67, the determination unit 68, and the determination unit 69), the writing data processing unit 70, the data processing unit 71, the writing control unit 72, and the transmission processing unit 74, and information being operated are stored in the memory 112 each time.

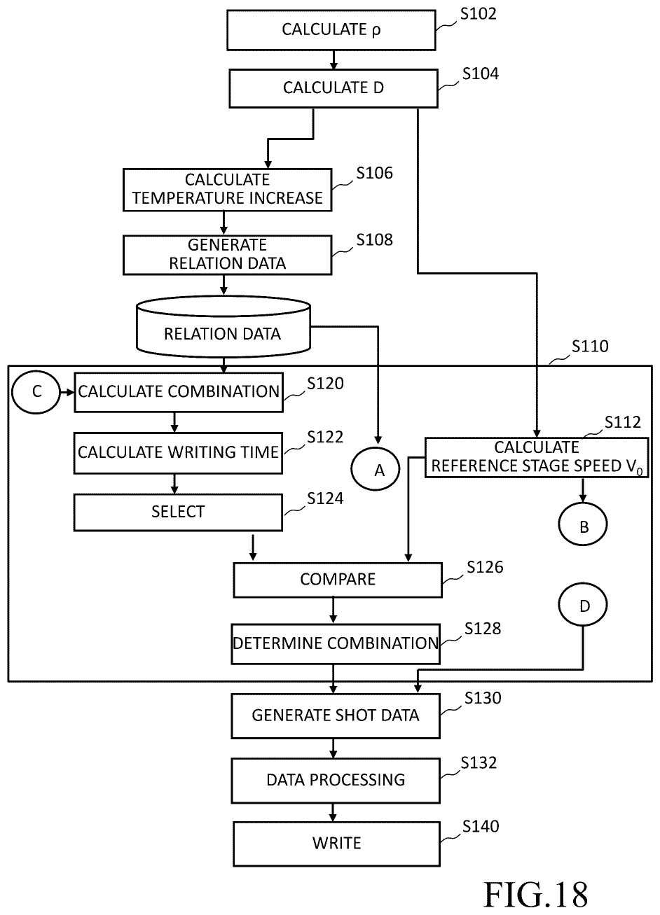

FIG. 18 is a flowchart showing an example of some portions of main steps of a writing method according to the second embodiment.

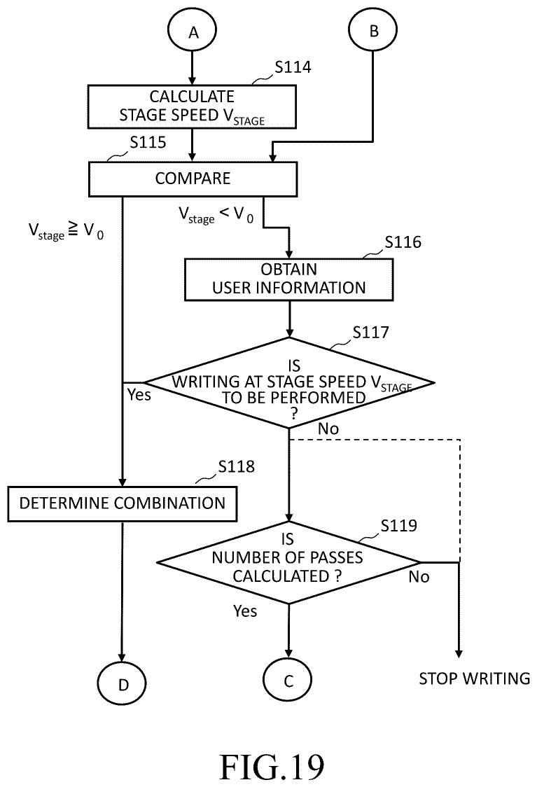

FIG. 19 is a flowchart showing an example of the other portions of the main steps of the writing method according to the second embodiment.

The contents of FIGS. 18 and 19 are the same as those of FIG. 9 except that, as internal steps of the combination obtaining step (S110), there are added a stage speed V_{stage} calculation step (S114), a comparison step (S115), a user information obtaining step (S116), a determination step

(S117), a combination determination step (S118), and a determination step (S119), and that, based on a result of the determination step (S119), it is determined whether the combination calculation step (S120), the writing time calculation step (S122), the selection step (S124), and the comparison step (S126) have already been performed.

The contents of each step from the pattern density calculation step (S102) to the relation data generation step (S108) are the same as those of the first embodiment.

In the combination obtaining step (S110), the combination obtaining unit 56 reads relation data from the storage device 144, for example, and obtains, using the relation data, a stage speed at which a resist temperature increase is equal to or less than a preset allowable temperature increase. Specifically, it operates as follows:

The contents of the reference stage speed calculation step (S112) are the same as those of the first embodiment.

In the stage speed V_{stage} calculation step (S114), in the case where the multiplicity of multiple writing is predetermined, the stage speed calculation unit 64 reads relation data from the storage device 144, for example, and, using the relation data, calculates a maximum stage speed at which a temperature increase of the resist is within an allowable temperature increase based on the predetermined multiplicity and resist sensitivity of the resist, as a stage speed V_{stage}. The method for this calculation is the same as the method for calculating a maximum stage speed V_{stage} by the combination obtaining unit 56 in the Case 1 of the first embodiment.

In the comparison step (S115), the comparison unit 66 compares a calculated stage speed V_{stage} with a reference stage speed V₀ at the preset multiplicity. As a result of the comparison, if a calculated stage speed V_{stage} is equal to or greater than the reference stage speed V₀, it proceeds to the combination determination step (S128). As a result of the comparison, if a calculated stage speed V_{stage} is less than the reference stage speed V₀, information indicating that the calculated stage speed V_{stage} is less than the reference stage speed V₀ is output to the user, and it proceeds to the user information obtaining step (S116). For example, the information may be displayed on a touch panel (not shown), or output to the outside.

In the user information obtaining step (S116), the user information obtaining unit 67 obtains, from the user, information indicating whether writing is to be performed at a calculated stage speed V_{stage}, and information indicating whether the multiplicity (the number of passes) of multiple writing is to be changed or not when writing is not performed at the calculated stage speed V_{stage}. For example, a selection button is displayed on a touch panel (not shown) to be selected by the user.

In the determination step (S117), the determination unit 68 determines whether writing is to be performed at a calculated stage speed V_{stage}, in accordance with information acquired from the user. If writing at a calculated stage speed V_{stage}, it proceeds to the combination determination step (S128). If not writing at a calculated stage speed V_{stage}, it proceeds to the determination step (S119).

In addition, in the user information obtaining step (S116), when writing is not performed at a calculated stage speed V_{stage}, it is also preferable to obtain information indicating “unwritable” instead of information indicating whether the multiplicity (the number of passes) of multiple writing is to be changed or not. In that case, that is, when writing is not performed at a calculated stage speed V_{stage}, writing is stopped (dotted line) as being “unwritable”.

In the combination determination step (S118), when a calculated stage speed V_{stage} is equal to or less than the reference stage speed V₀, the combination determination unit 63 determines the combination of preset multiplicity and the stage speed V_{stage} as a combination used writing conditions. When a calculated stage speed V_{stage} is equal to or greater than the reference stage speed V₀, the combination determination unit 63 determines the combination of preset multiplicity and the reference stage speed V₀ as a combination used writing conditions. Then, it proceeds to the shot data generation step (S130).

In the determination step (S119), the determination unit 69 determines whether the multiplicity (the number of passes) of multiple writing is to be changed in accordance with information acquired from the user. When the multiplicity (the number of passes) of multiple writing is to be changed, it proceeds to the combination calculation step (S120), and performs each step from the combination calculation step (S120) to the combination determination step (S128) by the method of the Case 2 in the first embodiment. Then, it proceeds to the shot data generation step (S130). When the multiplicity (the number of passes) of multiple writing is not to be changed, writing is stopped (dotted line) as being “unwritable”.

The contents of each step after the shot data generation step (S130) are the same as those of the first embodiment. Therefore, when using preset multiplicity, the writing mechanism 150 writes a pattern on the substrate 101 placed on the XY stage 105 with the multiple beams 20 while moving the stage at a stage speed according to the relation between the reference stage speed Vo and an obtained stage speed V_{stage}.

As described above, according to the second embodiment, it is possible to select whether writing is to be stopped by the user and/or to select whether multiplicity (number of passes) is to be changed.

Embodiments have been explained referring to specific examples described above. However, the present invention is not limited to these specific examples.

Functions of processing described in the first embodiment may be executed by a computer. A program for causing a computer to implement such functions of processing may be stored in a non-transitory tangible computer-readable storage medium such as a magnetic disk drive.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

A multiple charged particle beam writing apparatus according to at least one of the embodiments described above includes
a storage device to store therein relation data among a stage speed of a stage on which a substrate coated with resist is to be placed, a dose for each writing processing of multiple writing, and a temperature increase of the resist,
a combination obtaining circuit to read the relation data from the storage device, and to obtain, using the relation data, a combination of a stage speed, at which writing can be performed in a range where the temperature increase of the resist is within an allowable temperature increase, and multiplicity of the multiple writing, and
a writing mechanism to include the stage and an optical system which generates multiple charged particle beams and controls a trajectory of the multiple charged particle beams, and to write a pattern with the multiple charged particle beams onto the substrate placed on the stage through writing processing in accordance with an obtained combination of the stage speed and the multiplicity.

A non-transitory computer-readable storage medium, according to at least one of the embodiments described above, stores a program for causing a computer to execute processing including
storing, in a storage device, relation data among a stage speed of a stage on which a substrate coated with resist is to be placed in multiple beam writing, a dose for each writing processing of multiple writing, and a temperature increase of the resist, and
reading the relation data from the storage device, obtaining, using the relation data, a combination of a stage speed, at which writing can be performed in a range where the temperature increase of the resist is within an allowable temperature increase, and multiplicity of the multiple writing, and outputting an obtained combination.

A multiple charged particle beam writing method according to at least one of the embodiments described above includes
storing, in a storage device, relation data among a stage speed of a stage for performing writing on a substrate with a charged particle beam while moving the stage on which the substrate coated with resist is placed, a dose for one writing processing, and a temperature increase of the resist,
reading the relation data from the storage device, and obtaining, using the relation data, a stage speed at which the temperature increase of the resist is equal to or less than a preset allowable temperature increase, and
writing a pattern on the substrate placed on the stage with multiple charged particle beams while moving the stage at a stage speed associated with a relation between a reference stage speed and an obtained stage speed.

A stage speed obtaining apparatus according to at least one of the embodiments described above, for obtaining a stage speed to perform writing on a substrate with a charged particle beam while moving a stage on which the substrate coated with resist is placed, includes
a storage device to store therein relation data among a stage speed of the stage, a dose for one writing processing, and a temperature increase of the resist, and
a stage speed obtaining circuit to read the relation data from the storage device, and obtain, using the relation data, a stage speed at which the temperature increase of the resist is equal to or less than a preset allowable temperature increase.

A multiple charged particle beam writing apparatus according to at least one of the embodiments described above includes
a storage device to store therein relation data among a stage speed of a stage on which a substrate coated with resist is to be placed, a dose for one writing processing, and a temperature increase of the resist,
a stage speed obtaining circuit to read the relation data from the storage device, and obtain, using the relation data, a stage speed at which the temperature increase of the resist is equal to or less than a preset allowable temperature increase, and
a writing mechanism to write a pattern on the substrate placed on the stage with multiple charged particle beams while moving the stage at a stage speed associated with a relation between a reference stage speed and an obtained stage speed.

A non-transitory computer-readable storage medium, according to at least one of the embodiments described above, stores a program for causing a computer to execute processing including
storing, in a storage device, relation data among a stage speed of a stage for performing writing on a substrate with a charged particle beam while moving the stage on which the substrate coated with resist is placed, a dose for one writing processing, and a temperature increase of the resist, and
reading the relation data from the storage device, obtaining, using the relation data, a stage speed at which the temperature increase of the resist is equal to or less than a preset allowable temperature increase, and outputting an obtained stage speed.

A non-transitory computer-readable storage medium, according to at least one of the embodiments described above, stores a program for causing a computer to execute processing including
storing, in a storage device, relation data among a stage speed of a stage for performing writing on a substrate with a charged particle beam while moving the stage on which the substrate coated with resist is placed, a dose for one writing processing, and a temperature increase of the resist,
reading the relation data from the storage device, and obtaining, using the relation data, a stage speed at which the temperature increase of the resist is equal to or less than a preset allowable temperature increase, and
writing a pattern on the substrate placed on the stage with multiple charged particle beams while moving the stage at a stage speed associated with a relation between a reference stage speed and an obtained stage speed.

Furthermore, any stage speed obtaining method, stage speed obtaining apparatus, multiple charged particle beam writing apparatus, multiple charged particle beam writing method, method for obtaining a combination of a stage speed and multiplicity in multiple charged particle beam writing, and program (or non-transitory computer-readable storage medium storing a program) that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A stage speed obtaining method for performing writing on a substrate with a charged particle beam while moving a stage on which the substrate coated with resist is placed comprising:
storing, in a storage device, relation data among a stage speed of the stage, a dose for one writing processing, and a temperature increase of the resist; and
reading the relation data from the storage device by a processing circuit, obtaining, using the relation data, a stage speed at which the temperature increase of the resist is one of equal to and less than a preset allowable temperature increase, and outputting an obtained stage speed.

2. A multiple charged particle beam writing method comprising:
obtaining a stage speed using a stage speed obtaining method according to claim 1; and
writing a pattern on a substrate placed on a stage with multiple charged particle beams while moving the stage at a stage speed associated with a relation between a reference stage speed and the stage speed obtained.

3. The method according to claim 2 further comprising:
determining to be unwritable in a case of the reference stage speed being faster than an obtained stage speed.

4. The method according to claim 2 further comprising:
calculating, as the reference stage speed, a maximum stage speed in a range where writing processing can be performed.

5. The method according to claim 2, wherein
in a case where multiplicity of multiple writing is predetermined, using relation data among a stage speed of the stage, a dose for one writing processing, and a temperature increase of a resist, a stage speed at which a temperature increase of the resist is within an allowable temperature increase based on the multiplicity predetermined and a resist sensitivity of the resist is obtained as the stage speed, and
the pattern is written on the substrate in writing processing where the multiplicity predetermined and the stage speed obtained are used.

6. A multiple charged particle beam writing method comprising:
storing, in a storage device, relation data among a stage speed of a stage on which a substrate coated with resist is to be placed, a dose for each writing processing of multiple writing, and a temperature increase of the resist;
reading the relation data from the storage device, and obtaining, using the relation data, a combination of a stage speed, at which writing can be performed in a range where the temperature increase of the resist is within an allowable temperature increase, and multiplicity of the multiple writing; and
writing a pattern with multiple charged particle beams onto the substrate placed on the stage through writing processing in accordance with the combination obtained of the stage speed and the multiplicity.

7. The method according to claim 6, wherein the temperature increase of the resist is calculated, in each of a plurality of mesh regions obtained by dividing a writing region to be irradiated with the multiple charged particle beams, based on a representative value of doses of beams to be applied to one of the plurality of mesh regions, the stage speed, and a size in a writing movement direction of an irradiation region of the multiple charged particle beams.

8. The method according to claim 6 further comprising:
calculating a maximum temperature increase of the resist by using with varying a total dose of an irradiation region of the multiple charged particle beams and the stage speed; and
generating the relation data, by using the maximum temperature increase calculated of the resist.

9. The method according to claim 6, wherein, as the allowable temperature increase, a temperature increase of the resist having a temperature less than a resist dissolving temperature is used.

10. The method according to claim 6, wherein, as the allowable temperature increase, a temperature increase at which dimension accuracy of the pattern to be written is allowable is used.

11. The method according to claim 6, wherein,
with respect to the combination of the stage speed and the multiplicity, the multiplicity has been preset, and
the obtaining the combination includes, calculating, using the relation data, a maximum stage speed at which writing can be performed within the allowable temperature increase, depending on the multiplicity having been preset and an exposure sensitivity of the resist.

12. The method according to claim 6, wherein, the obtaining the combination includes
calculating a plurality of combinations each composed of the stage speed and the multiplicity, depending on an exposure sensitivity of the resist, and
selecting, out of the plurality of combinations, a combination according to which a writing time is shortest.

13. A method for obtaining a combination of a stage speed and multiplicity in multiple charged particle beam writing comprising:
storing, in a storage device, relation data among a stage speed of a stage on which a substrate coated with resist is to be placed, a dose for each writing processing of multiple writing, and a temperature increase of the resist; and
reading the relation data from the storage device, obtaining, using the relation data, a combination of a stage speed, at which writing can be performed in a range where the temperature increase of the resist is within an allowable temperature increase, and multiplicity of the multiple writing, and outputting the combination obtained.
